(19) United States
(12) Patent Application Publication
(10) Pub. No.: US 2016/0266500 A1
(43) Pub. Date: Sep. 15, 2016

(54) EXPOSURE APPARATUS, EXPOSURE METHOD, AND MANUFACTURING METHOD OF DEVICE

(71) Applicant: Kabushiki Kaisha Toshiba, Minato-ku (JP)

(72) Inventor: Nobuhiro KOMINE, Nagoya (JP)

(73) Assignee: Kabushiki Kaisha Toshiba, Minato-ku (JP)

(21) Appl. No.: 14/810,903

(22) Filed: Jul. 28, 2015

Related U.S. Application Data
(60) Provisional application No. 62/132,594, filed on Mar. 13, 2015.

(51) Int. Cl. G03F 7/20; G01B 11/06

(52) U.S. Cl. CPC G03F 7/70133; G01B 11/0608

(57) ABSTRACT

According to one embodiment, there is provided an exposure apparatus including a height measuring machine and a controller. The height measuring machine measures a height of a substrate coated with a photosensitive material. The controller can switch a condition under which the height measuring machine can perform a measurement, between a first measurement condition and a second measurement condition.

### CROSS-REFERENCE TO RELATED APPLICATIONS

This application is based upon and claims the benefit of priority from U.S. Provisional Application No. 62/132,594, filed on Mar. 13, 2015 the entire contents of which are incorporated herein by reference.

### FIELD

Embodiments described herein relate generally to an exposure apparatus, exposure method, and a manufacturing method of a device.

### BACKGROUND

In exposure apparatus, the height of a substrate is measured, and then the substrate is exposed to light. In view of this, it is desired to improve the throughput of the exposure process.

### BRIEF DESCRIPTION OF THE DRAWINGS

FIG. 1 is a diagram showing the configuration of an exposure apparatus according to an embodiment;

FIG. 2 is a diagram showing an example of first measurement conditions and second measurement conditions in the embodiment;

FIG. 3 is a diagram showing the configuration of a storage unit according to the embodiment;

FIG. 4 is a diagram showing a shot map for focus measurement (for a negative process) in the embodiment;

FIG. 5 is a diagram showing a shot map for focus measurement (for a positive process) in the embodiment;

FIG. 6 is a diagram showing a shot map for exposure in the embodiment;

FIG. 7 is a flow chart showing a method of manufacturing a semiconductor device (the negative process) in the embodiment; and

FIG. 8 is a flow chart showing a method of manufacturing a semiconductor device (the positive process) in the embodiment.

### DETAILED DESCRIPTION

In general, according to one embodiment, there is provided an exposure apparatus including a height measuring machine and a controller. The height measuring machine measures a height of a substrate coated with a photosensitive material. The controller can switch a condition under which the height measuring machine can perform a measurement, between a first measurement condition and a second measurement condition.

Exemplary embodiments of an exposure apparatus will be explained below in detail with reference to the accompanying drawings. The present invention is not limited to the following embodiments.

### Embodiment

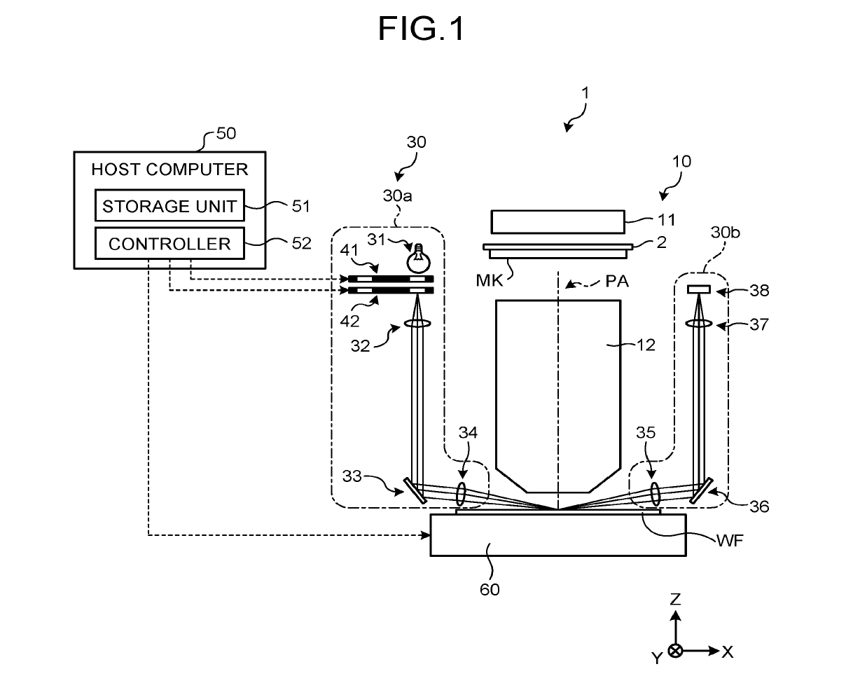

An exposure apparatus 1 according to the embodiment will be described using FIG. 1. FIG. 1 is a diagram showing the configuration of the exposure apparatus 1.

The exposure apparatus 1 is an apparatus for projection exposure of, e.g., a pattern drawn on a mask MK onto a wafer (substrate) WF coated with a resist (photosensitive material). Hereinafter, let +Z direction be a direction going away from the wafer WF along the optical axis PA of a projection optical system 12. Let X and Y directions be two directions orthogonal to each other in a plane perpendicular to the Z direction. Further, let directions about the X axis, Y axis, and Z axis be a θX direction, θY direction, and θZ direction respectively.

The exposure apparatus 1 has an optical system 10, a mask stage 2, a wafer-alignment detecting system (not shown), a focus detecting system (height measuring machine) 30, a host computer 50, and a wafer stage (substrate stage) 60.

The host computer 50 has a storage unit 51, and a controller 52. The controller 52 controls the components of the exposure apparatus 1 comprehensively. The storage unit 51 stores information necessary for control by the controller 52.

The optical system 10 is used to expose the wafer WF. The optical system 10 has an illumination optical system 11 and the projection optical system 12. The illumination optical system 11, the mask stage 2, and the projection optical system 12 are positioned with the optical axis PA as the center. The optical axis PA is an axis indicating the direction in which the chief ray of exposure light travels from an exposure light source (not shown) to the wafer WF.

The wafer stage 60 holds the wafer WF. The wafer stage 60 moves in the X, Y, and Z directions and rotates in the θX, θY, and θZ directions while holding the wafer WF. Thus, the wafer stage 60 positions the wafer WF.

The mask stage 2 is placed in the +Z direction from the wafer stage 60 with the projection optical system 12 in between. The projection optical system 12 projects, by exposure, incident light through the mask MK onto the wafer WF to form an image on the wafer WF that corresponds to a pattern drawn on the mask MK.

The illumination optical system 11 is placed in the +Z direction from the mask stage 2. The illumination optical system 11 illuminates the illumination area of the mask MK with exposure light having a uniform illumination distribution. The exposure light is diffracted by the pattern drawn on the mask MK and incident on the projection optical system 12.

The wafer-alignment detecting system (not shown) performs alignment measurement to detect the position in the X and Y directions (position in a planar direction) of the wafer WF.

The focus detecting system 30 irradiates light onto the wafer WF and detects light reflected by the wafer WF, thereby measuring the height of the wafer WF.

The focus detecting system 30 has a projecting system 30a and a light receiving system 30b. The projecting system 30a and the light receiving system 30b are opposite each other and located in an obliquely upward direction from a measurement subject (e.g., the wafer WF). The projecting system 30a has a projection light source 31, a lens 32, a mirror 33, and a lens 34. The light receiving system 30b has a lens 35, a mirror 36, a lens 37, and a detector 38.

Light emitted by the projection light source 31 travels in the −Z direction along the optical axis, passes through the lens 32, is reflected by the mirror 33 to travel in the +X direction, passes through the lens 34, and then forms an image of a predetermined shape on, and is reflected by, the wafer WF. The reflected light travels in the +X direction, passes through the lens 35, is reflected by the mirror 36 to travel in the +Z direction along the optical axis and pass through the lens 37, and re-forms an image of a predetermined shape on the detector 38. With this operation, the focus detecting system 30 performs focus measurement to detect the position of the wafer WF along the Z direction (height direction).

The focus detecting system 30 is configured such that measurement conditions for focus measurement can be switched between first measurement conditions and second measurement conditions. The first measurement conditions are measurement conditions under which the resist (photosensitive material) does not sense light. The second measurement conditions are measurement conditions under which the resist senses light. The first measurement conditions include a first wavelength and a first exposure amount with which the resist does not sense light. The second measurement conditions include a second wavelength and a second exposure amount with which the resist senses light.

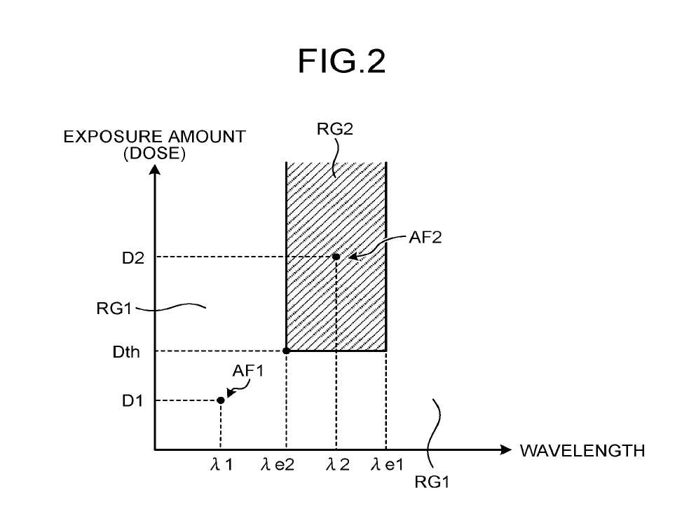

For example, in a plane with the light wavelength and the exposure amount of a substrate as its two axes as shown in FIG. 2, a region RG2 indicated by oblique hatching denotes wavelengths and exposure amounts with which the resist senses light, and the region RG1 outside the region RG2 denotes wavelengths and exposure amounts with which the resist does not sense light. FIG. 2 is a diagram showing an example of the first measurement conditions and second measurement conditions. The region RG2 is one whose light wavelengths are less than or equal to the upper limit λe1 of the resist light-sensing wavelength and greater than or equal to the lower limit λe2 and whose exposure amounts of the substrate are greater than or equal to a predetermined threshold Dth. In the case of FIG. 2, the first measurement conditions include measurement conditions AF1, and the second measurement conditions include measurement conditions AF2. The measurement conditions AF1 has a wavelength λ1 and an exposure amount D1 included in the region RG1. That is, the first wavelength includes the wavelength λ1, and the first exposure amount includes the exposure amount D1. The measurement conditions AF2 has a wavelength 22 and an exposure amount D2 included in the region RG2. That is, the second wavelength includes the wavelength λ2, and the second exposure amount includes the exposure amount D2.

Referring back to FIG. 1, for example, the projecting system 30a further has a light amount filter 41 and a wavelength filter 42.

The light amount filter 41 is configured to be insertable into the optical path from the projection light source 31 to the wafer WF. Although FIG. 1 illustrates the case where the light amount filter 41 can be inserted between the projection light source 31 and the lens 32, the position at which the light amount filter 41 can be inserted may be another position as long as it is on the optical path from the projection light source 31 to the wafer WF. The controller 52 switches between the state of the light amount filter 41 being inserted in the optical path and the state of the light amount filter 41 being evacuated from the optical path. With this operation, the controller 52 switches the exposure amount for the wafer WF between the second exposure amount and the first exposure amount. For example, the state of the light amount filter 41 being inserted in the optical path may correspond to the second exposure amount, and the state of the light amount filter 41 being evacuated from the optical path may correspond to the first exposure amount, or vice versa.

The wavelength filter 42 is configured to be insertable into the optical path from the projection light source 31 to the wafer WF. Although FIG. 1 illustrates the case where the wavelength filter 42 can be inserted between the projection light source 31 and the lens 32, the position at which the wavelength filter 42 can be inserted may be another position as long as it is on the optical path from the projection light source 31 to the wafer WF. The controller 52 switches between the state of the wavelength filter 42 being inserted in the optical path and the state of the wavelength filter 42 being evacuated from the optical path. With this operation, the controller 52 switches the light wavelength for the wafer WF between the second wavelength and the first wavelength. For example, the state of the wavelength filter 42 being inserted in the optical path may correspond to the second wavelength, and the state of the wavelength filter 42 being evacuated from the optical path may correspond to the first wavelength, or vice versa.

That is, the controller 52 can switch the operation of the focus detecting system (height measuring machine) 30 between for the first measurement conditions and for the second measurement conditions. For example, the surface of the wafer WF is divided into a periphery region PR and a device region ER. The device region ER is a region onto which device patterns are to be transferred and is placed inward of the periphery region PR. Where a negative resist is coated over the wafer WF (a negative process), the controller 52 controls the focus detecting system 30 to measure the height of the periphery region PR under the second measurement conditions and to measure the height of the device region ER under the first measurement conditions. Where a positive resist is coated over the wafer WF (a positive process), the controller 52 controls the focus detecting system 30 to measure the heights of all the regions (periphery region PR and device region ER) under measurement conditions fixed at the first measurement conditions.

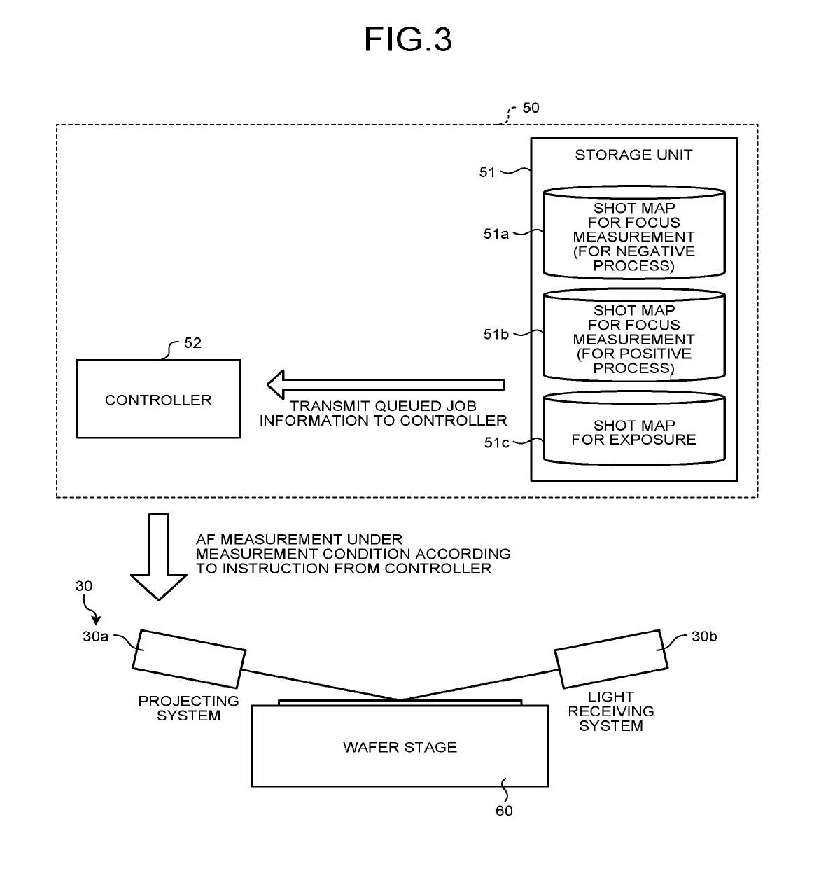

The storage unit 51 stores shot maps 51a to 51c beforehand as shown in FIG. 3. FIG. 3 is a diagram showing the configuration of the storage unit 51.

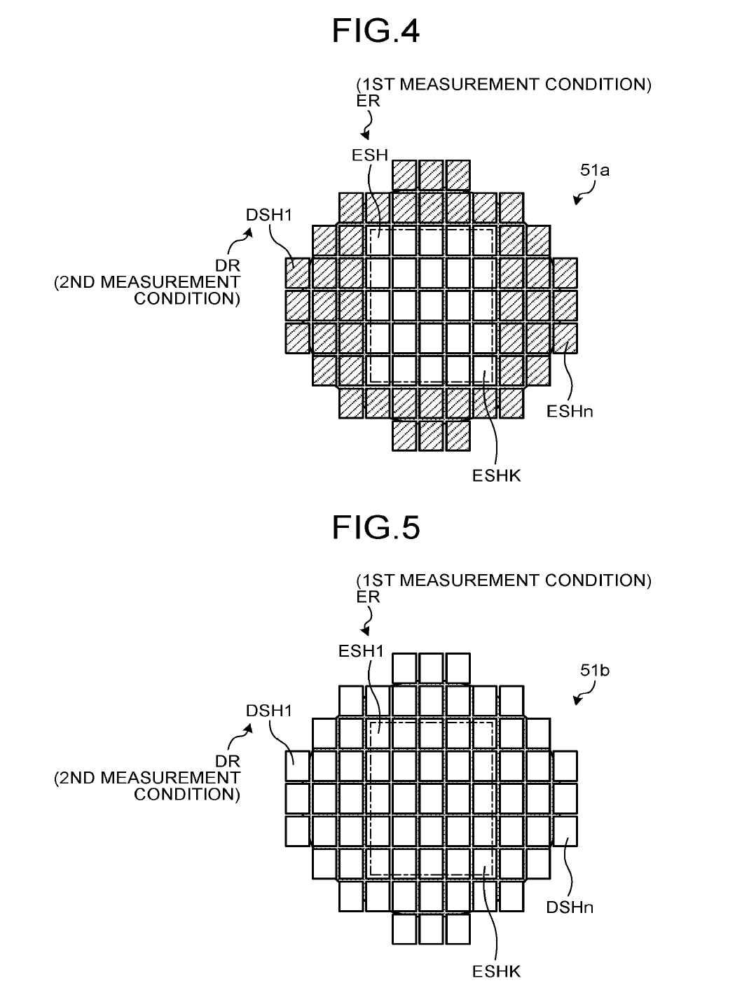

The shot map 51a is a shot map for focus measurement for the case where the wafer WF to be processed is a wafer for the negative process and includes information shown in, e.g., FIG. 4. FIG. 4 is a diagram showing the shot map for focus measurement (for the negative process) 51a. The shot map 51a includes information about the placement positions of multiple shot areas DSH1 to DSHn and ESH1 to ESHk on the wafer WF and information about measurement conditions for the shot areas DSH1 to DSHn and ESH1 to ESHk. The shot areas DSH1 to DSHn and ESH1 to ESHk include multiple dummy shot areas DSH1 to DSHn and multiple effective shot areas ESH1 to ESHk. The dummy shot areas DSH1 to DSHn are placed in the periphery region PR (the region outside a dot-dashed line shown in FIG. 4) of the wafer WF. The effective shot areas ESH1 to ESHk are placed in the device region ER (the region inside the dot-dashed line shown in FIG. 4) of the wafer WF.

In the shot map 51a, the dummy shot areas DSH1 to DSHn placed in the periphery region PR are associated with the second measurement conditions, and the effective shot areas ESH1 to ESHk placed in the device region ER are associated with the first measurement conditions. If determining that the wafer WF to be processed is a wafer for the negative process based on recipe information, the host computer 50 reads the shot map 51a from the storage unit 51 to transfer to the controller 52. Thus, the controller 52, based on the shot map (map information) 51a, controls the focus detecting system 30 to measure the height of the periphery region PR under the second measurement conditions and to measure the height of the device region ER under the first measurement conditions.

The shot map 51b is a shot map for focus measurement for the case where the wafer WF to be processed is a wafer for the positive process and includes information shown in, e.g., FIG. 5. FIG. 5 is a diagram showing the shot map for focus measurement (for the positive process) 51b. The shot map 51b includes information about the placement positions of multiple shot areas DSH1 to DSHn and ESH1 to ESHk on the wafer WF and information about measurement conditions for the shot areas DSH1 to DSHn and ESH1 to ESHk.

In the shot map 51b, the shot areas DSH1 to DSHn and ESH1 to ESHk are associated with the first measurement conditions. That is, the dummy shot areas DSH1 to DSHn placed in the periphery region PR and the effective shot areas ESH1 to ESHk placed in the device region ER are both associated with the first measurement conditions. If determining that the wafer WF to be processed is a wafer for the positive process based on recipe information, the host computer 50 reads the shot map 51b from the storage unit 51 to transfer to the controller 52. Thus, the controller 52, based on the shot map (map information) 51b, controls the focus detecting system 30 to measure the heights of all the regions (periphery region PR and device region ER) under measurement conditions fixed at the first measurement conditions.

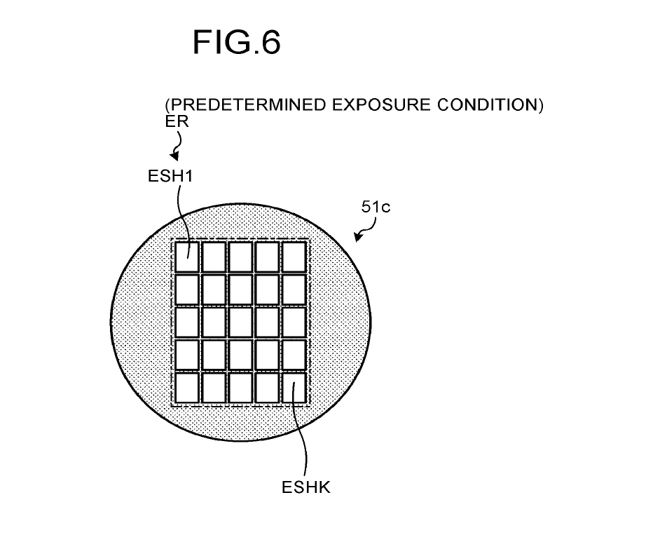

The shot map 51c is a shot map for exposure and includes information shown in, e.g., FIG. 6. FIG. 6 is a diagram showing the shot map for exposure (for the positive process) 51c. The shot map 51c includes information about the placement positions of multiple shot areas ESH1 to ESHk on the wafer WF and information about predetermined exposure conditions for the shot areas ESH1 to ESHk. The shot map 51c does not include information about the dummy shot areas DSH1 to DSHn. If determining that it is time to perform exposure, the host computer 50 reads the shot map 51c from the storage unit 51 to transfer to the controller 52. Thus, the controller 52, based on the shot map (map information) 51c, controls the optical system 10 and the wafer stage 60 to perform exposure on the device region ER.

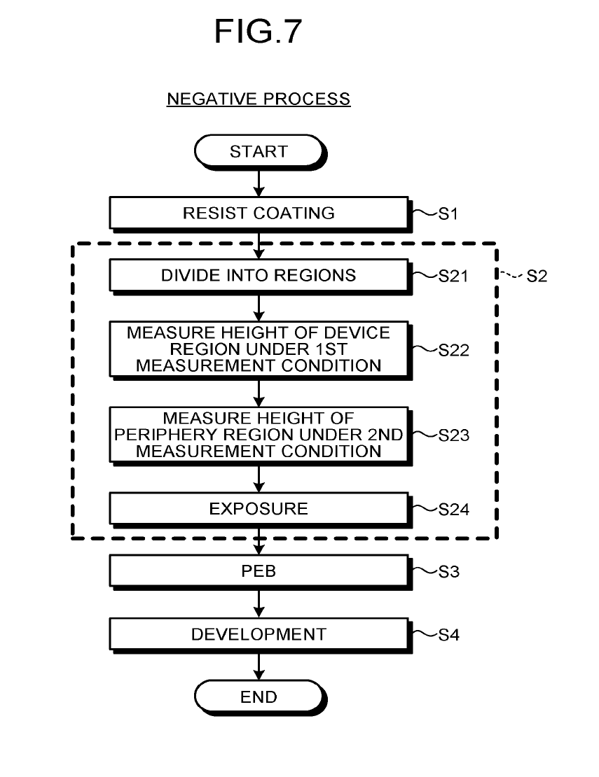

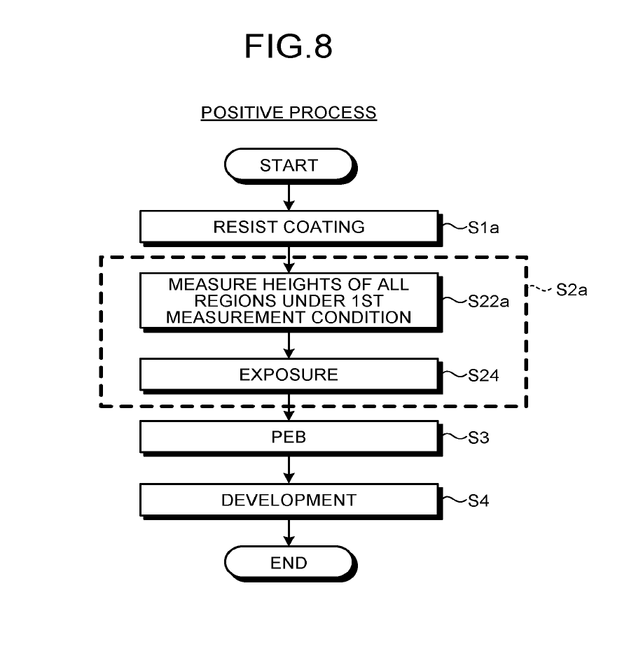

Next, a method of manufacturing a semiconductor device using the exposure apparatus 1 will be described using FIGS. 7 and 8. FIG. 7 is a flow chart showing a method of manufacturing a semiconductor device (the negative process). FIG. 8 is a flow chart showing a method of manufacturing a semiconductor device (the positive process).

If the wafer WF to be processed is a wafer for the negative process, the steps shown in FIG. 7 are executed. A transport system transports the wafer WF to a coating apparatus. The coating apparatus coats, e.g., a negative resist over the wafer WF according to recipe information (S1). The transport system transports the wafer WF coated with the negative resist from the coating apparatus to the exposure apparatus 1.

The exposure apparatus 1 performs the exposure process (S2). Specifically, the host computer 50 determines that the wafer WF to be processed is a wafer for the negative process based on recipe information and reads the shot map 51a for the negative process from the storage unit 51 to transfer to the controller 52. The controller 52 divides the surface of the wafer WF into the periphery region PR and device region ER based on the shot map 51a (S21). The controller 52, based on the shot map 51a, controls the focus detecting system 30 to measure the heights of the effective shot areas ESH1 to ESHk placed in the device region ER under the first measurement conditions (S22). The controller 52, based on the shot map 51a, controls the focus detecting system 30 to measure the heights of the dummy shot areas DSH1 to DSHn placed in the periphery region PR under the second measurement conditions (S23). The controller 52 obtains the amount of deviation along the Z direction from a target position (e.g., a position on a horizontal plane) for each measurement position based on the results of the height measurement (S22, S23). The controller 52 obtains the correction amount along the Z direction for each measurement position according to the obtained amount of deviation. The controller 52 controls the wafer stage 60 according to the obtained correction amount such that the substrate holding surface becomes flat. With the wafer stage being in this state, the controller 52, based on the shot map 51c, controls the optical system 10 and the wafer stage 60 to perform exposure on the device region ER (S24). Thus, the pattern of the mask MK is transferred as a latent image into the resist on the wafer WF. In this exposure (S24), the exposure of the dummy shot areas is omitted.

After the exposure process (S2) finishes, the transport system transports the exposed wafer WF from the exposure apparatus 1 to a heat treater. The heat treater heat-treats the wafer WF (PEB: post-exposure bake) (S3).

The transport system transports the wafer WF from the heat treater to a developing apparatus. The developing apparatus develops the latent image formed on the wafer WF with use of a predetermined developing liquid (S4). Then processing such as dry etching is performed on the wafer WF with the developed resist pattern as a mask.

In contrast, if the wafer WF to be processed is a wafer for the positive process, the steps shown in FIG. 8 are executed. The transport system transports the wafer WF to the coating apparatus. The coating apparatus coats, e.g., a positive resist over the wafer WF according to recipe information (S1a). The transport system transports the wafer WF coated with the positive resist from the coating apparatus to the exposure apparatus 1.

The exposure apparatus 1 performs the exposure process (S2a). Specifically, the host computer 50 determines that the wafer WF to be processed is a wafer for the positive process based on recipe information and reads the shot map 51b for the positive process from the storage unit 51 to transfer to the controller 52. The controller 52, based on the shot map 51b for the positive process, controls the focus detecting system 30 to measure the heights of the shot areas DSH1 to DSHn and ESH1 to ESHk of all the regions under the first measurement conditions (S22a). Then similar processes to S24, S3, S4 in FIG. 7 are sequentially executed.

Here, consider the case where, in the exposure process for the negative process, the heights are measured under measurement conditions fixed at the first measurement conditions and where exposure is performed with the exposure of the dummy shot areas being omitted. In this case, the negative resist not having sensed light on the periphery region PR is likely to be removed by the development process, so that the surface in the periphery region PR of the wafer WF is likely to be exposed. Thus, in processing such as dry etching thereafter, the periphery region PR of the wafer WF may be excessively processed. This excessive processing can generate dust, so that an anomaly may be induced in the performance in processing device patterns on the device region ER.

Further, consider the case where, in the exposure process for the negative process, the heights are measured under measurement conditions fixed at the first measurement conditions and where exposure is performed without the exposure of the dummy shot areas being omitted. In this case, after the height measurement, the exposure of the dummy shot areas DSH1 to DSHn as well as the exposure of the effective shot areas ESH1 to ESHk needs to be performed, and hence the throughput of the exposure process is likely to decrease. That is, the productivity of the exposure apparatus 1 is likely to decrease, so that the production cost of the semiconductor device may increase.

In contrast, in the embodiment, if the wafer WF to be processed is a wafer for the negative process, the controller 52 controls the focus detecting system 30 to measure the height of the periphery region PR under the second measurement conditions and to measure the height of the device region ER under the first measurement conditions. The first measurement conditions are measurement conditions under which the photosensitive material does not sense light. The second measurement conditions are measurement conditions under which the photosensitive material senses light. Thus, at height measurement, the negative resist on the periphery region PR can be caused to sense light, and hence even if thereafter exposure is performed with the exposure of the dummy shot areas being omitted (S24), the negative resist on the periphery region PR is hardly likely to be removed by the development process (S4). As a result, the occurrence of the excessive processing at the periphery region PR can be suppressed, and the productivity of the exposure apparatus 1 can be improved.

Further, in the embodiment, the process of causing the resist on the periphery region PR to sense light can be performed in parallel with measuring the height of the periphery region PR, and hence the throughput of the exposure process can be improved as compared with the case where the process of causing the resist on the periphery region PR to sense light is sequentially added.

It should be noted that, as to height-measurement subjects, the controller 52 may determine all the shot areas belonging to the periphery region PR and some shot areas belonging to the device region ER to be shot areas subject to measurement. In this case, in the exposure process (S2) shown in FIG. 7, the controller 52, based on the shot map 51a, controls the focus detecting system 30 to measure the heights of some effective shot areas ESH1 to ESHk placed in the device region ER under the first measurement conditions (S22). The controller 52, based on the shot map 51a, controls the focus detecting system 30 to measure the heights of all the dummy shot areas DSH1 to DSHn placed in the periphery region PR under the second measurement conditions (S23). In this case, at height measurement, the negative resist on the periphery region PR can be caused to sense light, and hence even if thereafter exposure is performed with the exposure of the dummy shot areas being omitted (S24), the negative resist on the periphery region PR is hardly likely to be removed by the development process (S4).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure apparatus comprising:
a height measuring machine that measures a height of a substrate coated with a photosensitive material; and
a controller that can switch a condition under which the height measuring machine can perform a measurement, between a first measurement condition and a second measurement condition.

2. The exposure apparatus according to claim 1, wherein
the height measuring machine irradiates light onto the substrate to detect light reflected by the substrate and to measure the height of the substrate.

3. The exposure apparatus according to claim 2, wherein
the first measurement condition includes measurement condition under which the photosensitive material does not sense light, and the second measurement condition includes measurement condition under which the photosensitive material senses light.

4. The exposure apparatus according to claim 3, wherein
the substrate includes a periphery region and a device region placed inward of the periphery region, and
wherein the controller controls the height measuring machine to measure the height of the periphery region under the second measurement condition and to measure the height of the device region under the first measurement condition.

5. The exposure apparatus according to claim 3, wherein
the first measurement condition include a first wavelength and a first exposure amount with which the photosensitive material does not sense light, and the second measurement condition include a second wavelength and a second exposure amount with which the photosensitive material senses light.

6. The exposure apparatus according to claim 5, wherein
the height measuring machine has a projecting system and a light receiving system, and
wherein when measuring the height of the periphery region, the controller controls the wavelength of light irradiated from the projecting system onto the substrate to be the second wavelength and the exposure amount for the substrate to be the second exposure amount and, when measuring the height of the device region, controls the wavelength of light irradiated from the projecting system onto the substrate to be the first wavelength and the exposure amount for the substrate to be the first exposure amount.

7. The exposure apparatus according to claim 6, wherein the projecting system has:
a light source;
a wavelength filter configured to be insertable into an optical path from the light source to the substrate; and
a light amount filter configured to be insertable into the optical path.

8. The exposure apparatus according to claim 7, wherein
the controller switches between the state of the wavelength filter being inserted in the optical path and the state of being evacuated from the optical path to switch the wavelength of light irradiated onto the substrate between the second wavelength and the first wavelength and switches between the state of the light amount filter being inserted in the optical path and the state of being evacuated from the optical path to switch the exposure amount for the substrate between the second exposure amount and the first exposure amount.

9. The exposure apparatus according to claim 1, further comprising a storage unit that stores map information in which, for each of multiple shot areas arranged on the substrate, the position of the shot area is associated with a measurement condition,
wherein the controller, based on the map information, measures the height of each of the multiple shot areas subject to measurement under a measurement condition selected from the first measurement condition and the second measurement condition.

10. The exposure apparatus according to claim 9, wherein
the substrate includes a periphery region and a device region placed inward of the periphery region, and
wherein in the map information, positions of shot areas belonging to the periphery region are associated with the second measurement condition, and positions of shot areas belonging to the device region are associated with the first measurement condition.

11. The exposure apparatus according to claim 10, wherein
the shot areas belonging to the periphery region are dummy shot areas.

12. The exposure apparatus according to claim 10, wherein
the controller determines all the shot areas belonging to the periphery region and at least some shot areas belonging to the device region to be the multiple shot areas subject to measurement.

13. The exposure apparatus according to claim 1, wherein
if the photosensitive material is a negative resist, the controller switches the condition between the first measurement condition and the second measurement condition.

14. The exposure apparatus according to claim 13, wherein
if the photosensitive material is a positive resist, the controller controls the condition to be a measurement condition fixed at the first measurement condition.

15. The exposure apparatus according to claim 1, further comprising:
a substrate stage that holds the substrate; and
an optical system that exposes the substrate to light,
wherein the controller measures the height of the substrate in the state where the substrate is held on the substrate stage and, after the measurement, has the optical system expose the substrate to light.

16. The exposure apparatus according to claim 15, wherein
while controlling the substrate stage such that a substrate holding surface becomes flat based on the measuring result of the height measuring machine, the controller has the optical system perform exposure operation.

17. The exposure apparatus according to claim 15, wherein
the substrate includes a periphery region and a device region placed inward of the periphery region, and
wherein the controller controls the substrate stage and the optical system to perform exposure operation on the device region without performing exposure operation on the periphery region.

18. An exposure method comprising:
measuring the height of a substrate coated with a photosensitive material while switching a condition of the measurement between a first measurement condition and a second measurement condition; and
after the measurement, exposing the substrate to light.

19. The exposure method according to claim 18, wherein
the measurement includes:
measuring the height of a periphery region on the substrate under the second measurement condition which causes the photosensitive material to sense light; and
measuring the height of a device region placed inward of the periphery region on the substrate under the first measurement condition which causes the photosensitive material not to sense light.

20. A manufacturing method of a device, comprising:
exposing a wafer to light by the exposure method according to claim 18; and
developing the exposed wafer.
